(19) United States
(12) Patent Application Publication
(10) Pub. No.: US 2024/0265972 A1
(43) Pub. Date: Aug. 8, 2024

(54) MEMORY APPARATUS PERFORMING PROGRAM OPERATION AND OPERATING METHOD THEREOF

(71) Applicant: SK hynix Inc., Icheon-si Gyeonggi-do (KR)

(72) Inventors: Hyung Jin CHOI, Icheon-si Gyeonggi-do (KR); Chan Hui JEONG, Icheon-si Gyeonggi-do (KR)

(73) Assignee: SK hynix Inc., Icheon-si Gyeonggi-do (KR)

(21) Appl. No.: 18/346,553

(22) Filed: Jul. 3, 2023

(30) Foreign Application Priority Data
Feb. 6, 2023 (KR) 10-2023-0015640

(51) Int. Cl. G11C 16/10; G11C 16/24; G11C 16/34

(52) U.S. Cl. CPC G11C 16/102; G11C 16/24; G11C 16/3459

(57) ABSTRACT

A memory device performs a coarse-program operation and a fine-program operation. During the coarse-program operation, the memory device selectively precharges a bit line to perform a verification. During the fine-program operation, the memory device precharges all bit lines to perform the verification.

### CROSS-REFERENCES TO RELATED APPLICATION

The present application claims priority under 35 U.S.C. § 119(a) to Korean application number 10-2023-0015640, filed on Feb. 6, 2023, in the Korean Intellectual Property Office, which is incorporated herein by reference in its entirety as set forth in full.

### BACKGROUND

### 1. Technical Field

Various embodiments generally relate to an integrated circuit, and, more particularly, to a non-volatile memory device configured to perform a program operation and an operating method thereof.

### 2. Related Art

Memory devices, which comprise one or more memory cells, can be classified into volatile memory devices and non-volatile memory devices depending on the characteristics of the memory cells. Volatile memory devices lose the data stored in a memory cell when power supply is interrupted. Non-volatile memory devices can maintain the data stored in a memory cell even when power is interrupted. Volatile memory devices may include a dynamic random-access memory (DRAM) and static RAM (SRAM). Non-volatile memory devices may include a read only memory (ROM), a programmable read only memory (PROM), an erasable PROM (EPROM), an electrically EPROM (EEPROM), a flash memory, a phase change RAM (PCRAM), a magnetic RAM (MRAM), a resistive RAM (RRAM) and a ferroelectric RAM (FRAM).

Non-volatile memory devices can perform program and verification operations The program operation stores or “writes” target data into memory cells. The verification operation confirms or verifies whether data written to memory cells corresponds to, i.e., is the stored target data. To improve memory capacity, multi-level cell (MLC), non-volatile memory devices have been developed, which are capable of storing more than 2 bits of data in a single memory cell. A MLC non-volatile memory device may thus need to perform a multiple number of program and verification operations. The multiple -number of times that program and verification operations may be required thus increases the power consumption and therefore can be an obstacle to reducing power consumption in a multi-level cell (MLC) non-volatile memory device.

### SUMMARY

In an embodiment, a memory device may include a bit line, a precharge control circuit and a page buffer. The bit line may be coupled to a memory cell. The precharge control circuit may be configured to generate a bit line precharge signal based on, i.e., responsive to, a program operation information signal. The page buffer may be configured to generate a latch signal based on, i.e., responsive to, program data and a voltage level of a sensing node, which is coupled to the bit line, and configured to precharge the bit line based on, i.e., responsive to, at least one of the bit line precharge signal and the latch signal.

In an embodiment, a memory device may include a bit line, a precharge control circuit and a page buffer. The bit line may be coupled to a memory cell. The precharge control circuit may be configured to generate a bit line precharge signal responsive to at least one of a program operation information signal and a verification information signal. The page buffer may be configured to generate a latch signal by sensing program data and a voltage level of a sensing node, which is coupled to the bit line, and configured to precharge the bit line responsive to at least one of the bit line precharge signal and the latch signal.

In an embodiment, a method of operating a memory device comprises, determining whether a program operation is a coarse-program operation or a fine-program operation; performing a program by applying a program voltage to a plurality of memory cells; and selectively precharging a plurality of bit lines to perform a verification when the program operation is the coarse-program operation, and precharging all the plurality of bit lines to perform the verification when the program operation is the fine-program operation.

### BRIEF DESCRIPTION OF THE DRAWINGS

FIG. 1 is a diagram illustrating the configuration of a memory device in accordance with an embodiment.

FIG. 2 is a diagram illustrating the configuration of a memory block in accordance with an embodiment.

FIG. 3 is a diagram illustrating the configuration of a memory block in accordance with an embodiment.

FIGS. 4A and 4B are diagrams illustrating a threshold voltage distribution of memory cells formed because of a program operation performed by the memory device in accordance with an embodiment.

FIGS. 5A and 5B are diagrams illustrating a threshold voltage distribution of memory cells formed because of a program operation performed by the memory device in accordance with an embodiment.

FIG. 6 is a flowchart illustrating an operation of the memory device in accordance with an embodiment.

FIG. 7 is a flowchart illustrating an operation of the memory device in accordance with an embodiment.

FIG. 8A depicts a precharge control circuit.

FIG. 8B is a table illustrating operation states of the precharge control circuit.

FIG. 9 is a diagram illustrating the configuration of a page buffer in accordance with an embodiment.

FIG. 10 is a diagram illustrating the configuration of a data latch circuit illustrated in FIG. 9.

FIG. 11 is a diagram illustrating the configuration of a pass/fail latch circuit illustrated in FIG. 9.

FIG. 12 illustrates a processor coupled to a memory device as shown in FIG. 1.

### DETAILED DESCRIPTION

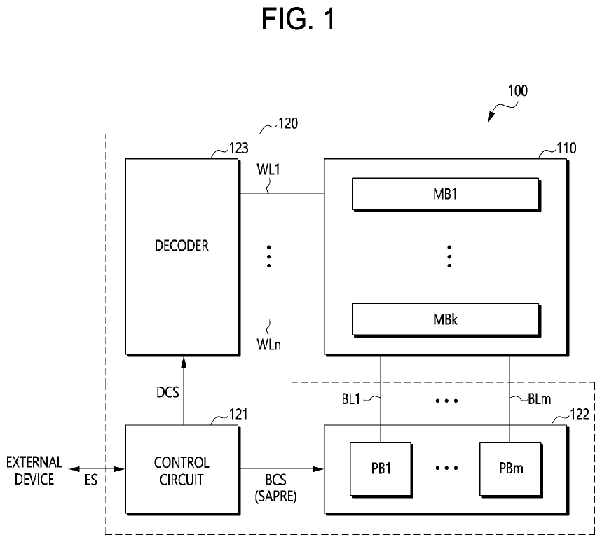

FIG. 1 is a diagram illustrating the configuration of a memory device 100 according to an embodiment of the present invention. The memory device 100 may include a memory cell array 110 and a peripheral circuit 120. The memory cell array 110 may include a plurality of memory blocks MB1 to MBk. A memory block may be a unit, on which the memory device 100 may perform program, verify and erase operations. The data stored in each of the plurality of memory blocks MB1 to MBk can be erased at once, i.e., at the same time or simultaneously. Each of the plurality of memory blocks MB1 to MBk may include a plurality of memory cells (not shown in FIG. 1) each memory cell being configured to store data therein. The plurality of word lines WL1 to WLn (where ‘n’ is an integer of 2 or greater) and the plurality of bit lines BL1 to BLm (where ‘m’ is an integer of 2 or greater) may be arranged in each of the plurality of memory blocks MB1 to MBk. The plurality of memory cells may be coupled at the intersections where the plurality of word lines WL1 to WLn and the plurality of bit lines BL1 to BLm cross each other. Each memory cell may have an erase state and a plurality of program states, depending on the data stored therein and depending on whether the plurality of memory cells are single layer or multi-layer structures.

The plurality of memory cells may be arranged in a single-layer, i.e., two-dimensional structure, the single layer being at least substantially parallel to the substrate. The memory cells may also be arranged in multi-layer three-dimensional structure, having layers that are stacked above each other, “vertically” above the substrate, each of the layers being at least substantially parallel to each other as well as the substrate.

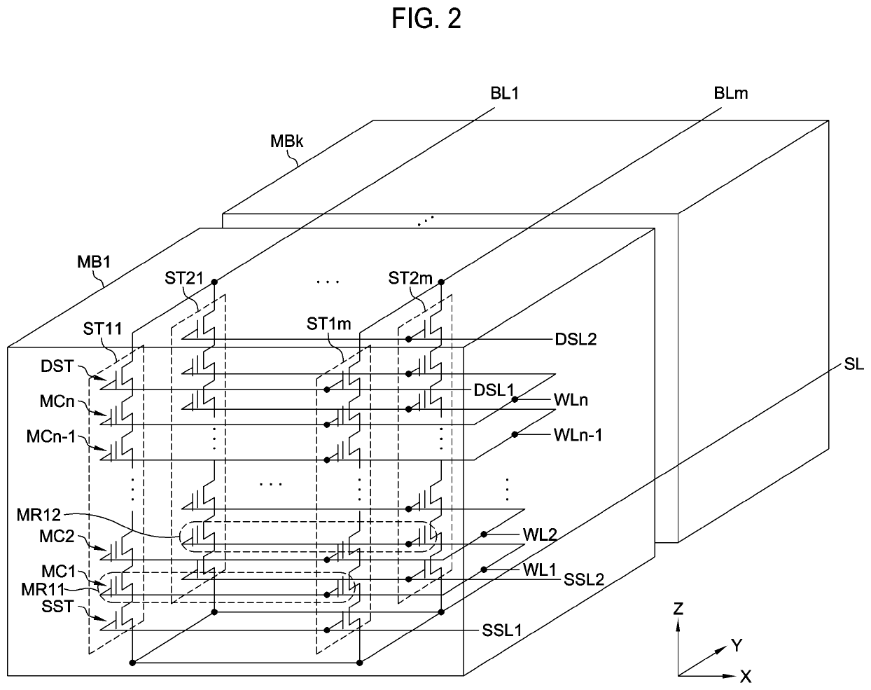

FIG. 2 is a diagram illustrating the configuration of a memory block MB1 in accordance with an embodiment. The memory block MB1 illustrated in FIG. 2 can be used to implement the memory blocks MB1 to MBk illustrated in FIG. 1. Referring to FIG. 2, the memory block MB1 may include serially-connected transistor strings ST11 to ST1m and ST21 to ST2m. As FIG. 2 is drawn, each of the strings ST11 to ST1m and ST21 to ST2m extends in the “vertical” direction (i.e., the Z direction). Within the memory block MB1, ‘m’ number of strings may be arranged horizontally in the row direction (i.e., the X direction). FIG. 2 shows two strings arranged horizontally in the column direction (i.e., the Y direction), for the sake of convenience and explanation. The memory block MB1 may have three or more strings in the column direction.

The strings ST11 to ST1m and ST21 to ST2m may be configured in the same way. For example, the string ST11 may include a source selection transistor SST, memory cells MC1 to MCn and a drain selection transistor DST, which are coupled to each other in series between a source line SL and the bit line BL1. The source of the source selection transistor SST may be coupled to the source line SL, and the drain of the drain selection transistor DST may be coupled to the bit line BL1. The transistors comprising memory cells MC1 to MCn may be coupled to each other in series, between the source selection transistor SST and the drain selection transistor DST.

The gates of the source selection transistors of the strings arranged in the same row may be coupled to the same source selection line.

For example, the gates of the source selection transistors of strings ST11 to ST1m in the first row may be coupled to a source selection line SSL1, while the gates of the source selection transistors of strings ST21 to ST2m in the second row may be coupled to a different source selection line SSL2. Alternatively, the source selection transistors of strings ST11 to ST1m and ST21 to ST2m may be commonly coupled to one source selection line as another embodiment.

The gates of the drain selection transistors of the strings arranged in the same row may be coupled to the same drain selection line. For example, the gates of the drain selection transistors of the strings ST11 to ST1m in the first row may be coupled to a drain selection line DSL1, while the gates of the drain selection transistors of the strings ST21 to ST2m in the second row may be coupled to a different drain selection line DSL2.

The strings arranged in the same column may be coupled to the same bit line. For example, the strings ST11 and ST21 in the first column may be coupled to the bit line BL1, while the strings ST1m and ST2m in the m-th column may be coupled to the bit line BLm.

The gates of the memory cells vertically located in the same location may be coupled to the same word line. For example, memory cells vertically located in the same location as the memory cell MC1 in the strings ST11 to ST1m and ST21 to ST2m may be coupled to the word line WL1.

Memory cells coupled to the same word line in the same row may form a single memory region. For example, memory cells coupled to the word line WL1 in the first row may form a memory region MR11. Memory cells coupled to the word line WL1 in the second row may form a memory region MR12. Depending on the number of rows, each word line may be coupled to a plurality of memory regions. Memory cells that form a single memory region may be programmed simultaneously. For example, a single memory region may configure a page.

According to an embodiment, the memory block MB1 may be further coupled to one or more dummy word lines other than the word lines WL1 to WLn and may include additional dummy memory cells coupled to the dummy word lines.

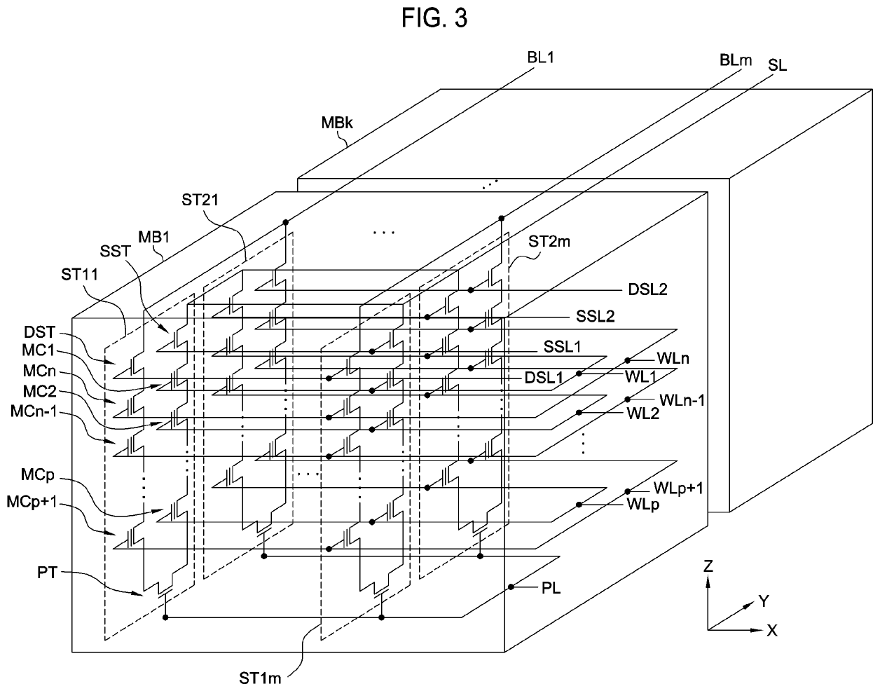

FIG. 3 is a diagram illustrating the configuration of a memory block MB1 in accordance with an embodiment. The memory block MB1 shown in FIG. 3 may be used to implement memory blocks MB1 to MBk shown in FIG. 1. Referring to FIG. 3, the memory block MB1 may include a plurality of strings ST11 to ST1m and ST21 to ST2m. Each of the strings ST11 to ST1m and ST21 to ST2m in FIG. 3 may be similar in configuration and operation to those in FIG. 2, except that the topology of the serially-connected transistors comprising each of the strings ST11 to ST1m and ST21 to ST2m in FIG. 3 may be substantially U-shaped with a pipe transistor PT at the “bottom” connected between the drains of transistors at the bottom of the U-shaped serially-connected transistors. The gate of each pipe transistor PT may be coupled to a pipeline PL. Among the memory cells MC1 to MCn, the memory cells MC1 to MCp may be sequentially arranged in the -Z direction and may be coupled in series between the source selection transistor SST and the pipe transistor PT. The memory cells MCp+1 to MCn among the memory cells MC1 to MCn may be sequentially arranged in the +Z direction and may be coupled in series between the pipe transistor PT and the drain selection transistor DST.

Referring back to FIG. 1, the peripheral circuit 120 may perform program, read, and erase operations on the memory cell array 110 under the control of an external device (not shown). The peripheral circuit 120 may receive from an external device one or more external signals ES, which may include a command signal, an address signal and data.

The peripheral circuit 120 may include a control circuit 121, a buffer group 122, and a decoder 123, as shown in FIG. 1. The control circuit 121 may control, i.e., cause the memory device 100 to perform various operations, based on the external signal ES. The control circuit 121 may generate buffer control signals BCS responsive to the external signal ES and may provide the buffer control signals BCS to the buffer group 122. The buffer control signals BCS may include a plurality of control signals to control the operation of the buffer group 122. The control circuit 121 may also generate a decoder control signal DCS responsive to the external signal ES and may provide the decoder control signal DCS to the decoder 123. For example, the decoder control signal DCS may include a plurality of program voltages, a plurality of verification voltages, a plurality of read voltages, an erase voltage, or a plurality of pass voltages, which have different voltage levels and are used in program operations. Although not shown, the control circuit 121 may also include an interface for communicating with the external device and may include a voltage generation circuit configured to generate various voltages with different voltage levels.

The buffer group 122 may be coupled to the memory cell array 110 via the plurality of bit lines BL1 to BLm. The buffer group 122 may include a plurality of page buffers PB1 to PBm, which are coupled to the respective bit lines BL1 to BLm on a one-to-one basis. The plurality of page buffers PB1 to PBm may temporarily store program data to be stored in target memory cells where program operation is performed. Among the plurality of page buffers PB1 to PBm, at least two page buffers may operate together responsive to the buffer control signals BCS, and program together, target memory cells coupled to each of the at least two, bit lines.

When memory cell programming is performed during the program operation and a program voltage is applied by the decoder 123 to a selected word line, the plurality of page buffers PB1 to PBm may provide, through the bit lines BL1 to BLm, a voltage corresponding to the data to be programmed into the selected memory cell coupled to the selected word line. For example, the memory cell coupled to the bit line, to which the program permission voltage is applied, may be controlled or “programmed” to require an increased threshold voltage. The threshold voltage of the memory cell coupled to the bit line, to which the program prohibition voltage is applied, may stay unchanged. During the program verification operation, the plurality of page buffers PB1 to PBm may read, through the bit lines BL1 to BLm, the data stored in the memory cells. Based on the buffer control signals BCS, the plurality of page buffers PB1 to PBm may precharge the bit lines BL1 to BLm and may detect the voltage level changes in the bit lines BL1 to BLm according to the data stored in the memory cells to determine whether the memory cells have the threshold voltage corresponding to the program data. The plurality of page buffers PB1 to PBm may store and output, a “pass” or a “fail” indication signals, as a result of the determination.

During the read operation, the plurality of page buffers PB1 to PBm may read, through the bit lines BL1 to BLm, data stored in memory cells of a selected page and may store the read data therein. During the erase operation, the plurality of page buffers PB1 to PBm may float the bit lines BL1 to BLm. In an embodiment, the buffer group 122 may further include a column decoding circuit to select a page responsive to the address signal.

The decoder 123 may be coupled to the memory cell array 110 through the word lines WL1 to WLn. The control circuit 121 may cause the decoder 123 to select, among the word lines WL1 to WLn, a target word line coupled to the target memory cells and may apply, to the target word line, program voltages and verification voltages of various levels. During the program operation, the control circuit 121 may cause the decoder 123 to apply a program voltage to the selected word line and apply a pass voltage to the non-selected word line. During the verification of the program operation, the control circuit may cause the decoder 123 to apply a verification voltage to the selected word line and apply a pass voltage to the non-selected word line. During the read operation, the control circuit 121 may cause the decoder 123 to apply a read voltage to the selected word line and apply a pass voltage to the non-selected word line. During the erase operation, the decoder 123 may apply a ground voltage to the plurality of word lines WL1 to WLn or might not apply any voltage to the plurality of word lines WL1 to WLn and may also raise the substrate voltage of the memory cell to the voltage level of the erase voltage, under the control of the control circuit 121. In an embodiment, the decoder 123 may include a row decoding circuit configured to select the word lines WL1 to WLn responsive to the address signal.

The memory device 100 may perform a stepwise program operation. more particularly, the memory device 100 may perform the coarse-program operation followed by a fine-program operation. The coarse-program operation may be a program operation of roughly forming or approximating a memory cell threshold voltage of the memory cell. The fine-program operation may be a program operation of precisely forming the memory cell threshold voltage. For programming efficiency, the memory device 100 may perform the coarse-program operation first and thereafter perform the fine-program operation. The control circuit 121 may control the decoder 123 and the buffer group 122 so that the memory device 100 stepwise performs the coarse-program operation and stepwise performs the fine-program operation. The coarse-program operation may be repeated numerous times until the target threshold voltage distribution is formed. Similarly, the fine-program operation may be repeated numerous times until the target threshold voltage distribution is formed. For example, the coarse-program operation may be repeated until the number of memory cells having threshold voltages higher than a first reference voltage becomes equal to or greater than a first predetermined number. The coarse-program operation may end when the number of memory cells having threshold voltages higher than the first reference voltage becomes equal to or greater than the first predetermined number. The fine-program operation may be repeated until the number of memory cells having threshold voltages lower than a second reference voltage becomes equal to or less than a second predetermined number. The fine-program operation may end when the number of memory cells having threshold voltages lower than the second reference voltage becomes equal to or less than the second predetermined number. The first and second reference voltages may have the same voltage level or different voltage levels. The first and second predetermined numbers may be the same as or different from each other. The first and second predetermined numbers may be independently set according to the characteristics of the memory device 100.

The coarse-program operation may include coarse programming and coarse programming-verification. The coarse-program may refer to applying a first coarse-program voltage to the selected word line, causing a change in the threshold voltage of the memory cell coupled to the selected word line. The coarse-verification may refer to applying a verification voltage to the selected word line and charging the bit line to determine whether current flows through the memory cell coupled to the selected word line. If current flows through the memory cell when the coarse programming verification voltage is applied to the selected word line, the coarse programming voltage level of the bit line may decrease and the threshold voltage of the memory cell may be determined as lower than the verification voltage. If current does not flow through the memory cell when the coarse programming verification voltage is applied to the selected word line, the coarse programming voltage level of the bit line may stay in a charged state and the threshold voltage of the memory cell may be determined as higher than the verification voltage. The pulse width and amplitude of the coarse-program voltage and the voltage level of the coarse programming verification voltage may vary in the plurality of coarse-program operations. For example, the pulse width of a second and different coarse-program voltage in the second coarse-program operation may be greater than first voltage that was used in the first coarse-program operation. The voltage level of the coarse program verification voltage in the second coarse-program operation may be higher than coarse program voltage that was used in the first coarse-program operation.

Similarly, the fine-program operation may include fine programming and fine programming-verification. The fine programming may refer to applying a first, fine-program voltage to the selected word line, causing a change in the threshold voltage of the memory cell coupled to the selected word line. The fine programming-verification may refer to applying a fine program verification voltage to the selected word line and charging the bit line to determine whether current flows through the memory cell coupled to the selected word line. If current flows through the memory cell when the first fine program verification voltage is applied to the selected word line, the first, fine program voltage level of the bit line may decrease and the threshold voltage of the memory cell may be determined as lower than the first, fine program verification voltage. If current does not flow through the memory cell when the first, fine program verification voltage is applied to the selected word line, the voltage level of the bit line may stay in a charged state and the threshold voltage of the memory cell may be determined as higher than the first, fine program verification voltage. The pulse width of the fine-program voltage and the voltage level of the verification voltage may vary in the plurality of fine-program operations. For example, the pulse width of the fine-program voltage in a second fine-program operation may be greater than the voltage used in the first fine-program operation. The voltage level of the second, fine program verification voltage in the second fine-program operation may be higher than the voltage in the first fine-program operation.

When the coarse-verification is performed during the coarse-program operation, the control circuit 121 may control the plurality of page buffers PB1 to PBm in the buffer group 122 to allow only the selected bit line to be precharged. When the fine-verification is performed during the fine-program operation, the control circuit 121 may control the plurality of page buffers PB1 to PBm in the buffer group 122 to allow all bit lines to be precharged. The control circuit 121 may generate a bit line precharge signal SAPRE, which is one of the control signals included in the buffer control signals BCS. Depending on whether the program operation is a coarse-program operation or a fine-program operation, the control circuit 121 may selectively enable the bit line precharge signal SAPRE. For example, when the coarse-program operation is performed, the control circuit 121 may disable the bit line precharge signal SAPRE and the plurality of page buffers PB1 to PBm may selectively precharge only at least some of the bit lines BL1 to BLm based on the program data and latch signal set by the control circuit 121. When the fine-program operation is performed, the control circuit 121 may enable the bit line precharge signal SAPRE and the plurality of page buffers PB1 to PBm may precharge, based on the bit line precharge signal SAPRE, the plurality of bit lines BL1 to BLm respectively coupled thereto.

In an embodiment, when the coarse-verification is performed during the coarse-program operation, the control circuit 121 may control the plurality of page buffers PB1 to PBm in the buffer group 122 so that only the selected bit line may be precharged. When the fine-verification is performed during the fine-program operation, the control circuit 121 may precharge only the selected bit line or all the bit lines depending on the distribution of memory cells targeted for the fine-verification. For example, when the fine-verification is performed on the distribution of memory cells having lower threshold voltages, the control circuit 121 may enable the bit line precharge signal SAPRE. When the fine-verification is performed on the distribution of memory cells having higher threshold voltages, the control circuit 121 may disable the bit line precharge signal SAPRE.

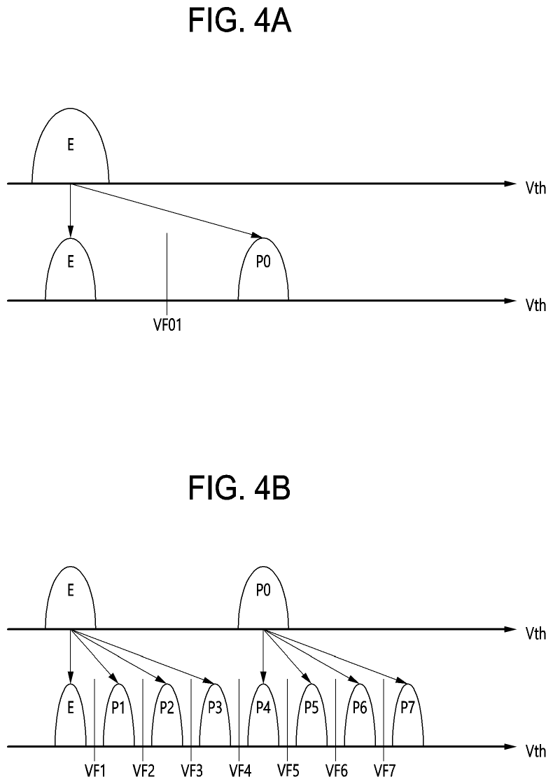

FIGS. 4A and 4B are diagrams illustrating a threshold voltage distribution of memory cells formed, by a program operation performed by the memory device 100 in accordance with an embodiment. In FIGS. 4A and 4B, the horizontal axis may represent the voltage level of the threshold voltage. Referring to FIG. 4A, prior to the program operation of the memory device 100, memory cells may be in an erased state.

During TLC programming, the memory device 100 may have eight different threshold voltage distributions. In order to form threshold voltage distributions, the memory device 100 may first perform a coarse-program operation as described above. For example, the memory device 100 may perform the coarse-program operation to roughly form a memory cell voltage distribution of an erase state E and a memory cell voltage distribution of a first coarse-program state P0. Memory cells in the first coarse-program state P0 may have first threshold voltages voltage levels of which are greater than the threshold voltages of the memory cells in the erase state E. After completion of the coarse-program that forms the memory cell voltage distribution of the first coarse-program state P0, the coarse-verification described above may be performed using a verification voltage VF0 having a voltage level between the memory cell voltage distributions of the erase state E and the first coarse-program state P0. The coarse-program operation may be repeated until the memory cell voltage distribution of the first coarse-program state P0 is formed.

After the coarse-program operation is completed, the memory device 100 may perform the fine-program operation, as described above. The memory device 100 may perform the fine-program operation to form a memory cell voltage distribution of the erase state E and memory cell voltage distributions of first to seventh fine-program states P1 to P7. Memory cells in the first to seventh fine-program states P1 to P7 may have second to eighth threshold voltages, respectively. The second threshold voltage has a voltage level slightly greater than the threshold voltage of memory cells in the erase state E, and the third to eighth threshold voltages may have sequentially greater voltage levels. For example, during the fine-program operation, memory cells in the erase state E by the coarse-program operation may be programmed to form memory cell distributions of the erase state E and the first to third fine-program states P1 to P3. During the fine-program operation, memory cells in first coarse-program state P0 by the coarse-program operation may be programmed to form memory cell distributions of fourth to seventh fine-program states P4 to P7. In an embodiment, after completion of the fine-program operation forming the memory cell distributions of the erase state E and the first to third program states P1 to P3, a fine-program operation may be performed to form the memory cell distributions of the fourth to seventh fine-program states P4 to P7. After completion of the fine-program forming the memory cell distribution of the first fine-program state P1, the fine-verification may be performed using a verification voltage VF1 having a voltage level between the memory cell distributions of the erase state E and the first fine-program state P1. After completion of the fine-program forming the memory cell distribution of the second fine-program state P2, the fine-verification may be performed using a verification voltage VF2 having a voltage level between the memory cell distributions of the first fine-program state P1 and the second fine-program state P2. After completion of the fine-program forming the memory cell distribution of the third fine-program state P3, the fine-verification may be performed using a verification voltage VF3 having a voltage level between the memory cell distributions of the second fine-program state P2 and the third fine-program state P3. After completion of the fine-program forming the memory cell distribution of the fourth fine-program state P4, the fine-verification may be performed using a verification voltage VF4 having a voltage level between the memory cell voltage distributions of the third fine-program state P3 and the fourth fine-program state P4. After completion of the fine-program forming the memory cell distribution of the fifth fine-program state P5, the fine-verification may be performed using a verification voltage VF5 having a voltage level between the memory cell distributions of the fourth fine-program state P4 and the fifth fine-program state P5. After completion of the fine-program forming the memory cell distribution of the sixth fine-program state P6, the fine-verification may be performed using a verification voltage VF6 having a voltage level between the memory cell distributions of the fifth fine-program state P5 and the sixth fine-program state P6. After completion of the fine-program forming the memory cell distribution of the seventh fine-program state P7, the fine-verification may be performed using a verification voltage VF7 having a voltage level between the memory cell distributions of the sixth fine-program state P6 and the seventh fine-program state P7.

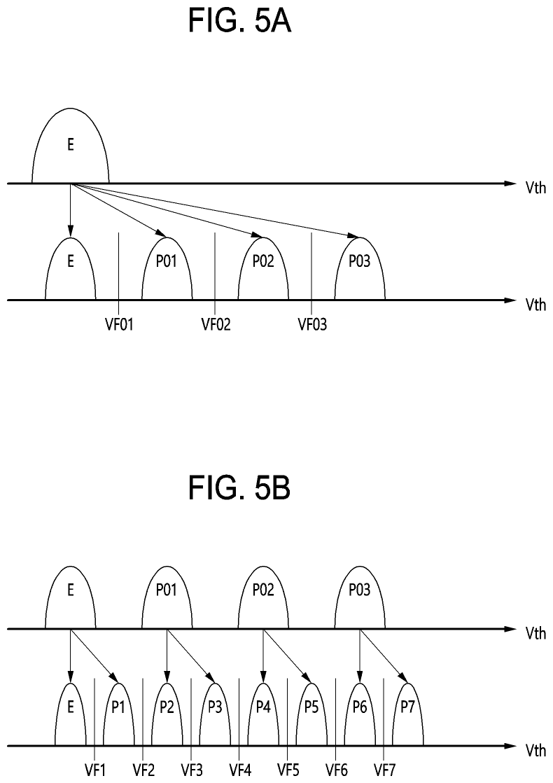

FIGS. 5A and 5B are diagrams illustrating a threshold voltage distribution of memory cells formed because of a program operation performed by the memory device 100 in accordance with an embodiment. Referring to FIG. 5A, the memory device 100 may perform the coarse-program operation first. For example, the memory device 100 may perform the coarse-program operation to form a memory cell distribution of the erase state E and memory cell distributions of first to third coarse-program states P01, P02 and P03. Memory cells in the first coarse-program state P01 may have a first threshold voltage, memory cells in the second coarse-program state P02 may have a second threshold voltage and memory cells in the third coarse-program state P03 may have a third threshold voltage. The first threshold voltage may have a higher voltage level than the threshold voltage of the memory cells in the erase state E. The second threshold voltage may have a higher voltage level than the first threshold voltage and the third threshold voltage may have a higher voltage level than the second threshold voltage. After completion of the coarse-program to form the memory cell distribution of the first coarse-program state P01, the coarse-verification may be performed using a verification voltage VF01 having a voltage level between the memory cell distributions of the erase state E and the first coarse-program state P01. After completion of the coarse-program to form the memory cell distribution of the second coarse-program state P02, the coarse-verification may be performed using a verification voltage VF02 having a voltage level between the memory cell distributions of the first coarse-program state P01 and the second coarse-program state P02. After completion of the coarse-program to form the memory cell distribution of the third coarse-program state P03, the coarse-verification may be performed using a verification voltage VF03 having a voltage level between the memory cell distributions of the second coarse-program state P02 and the third coarse-program state P03. The coarse-program operation may be repeated until the memory cell distribution of the first to third coarse-program states P01, P02 and P03 are formed.

After the coarse-program operation is completed, the memory device 100 may perform the fine-program operation to form a memory cell distribution of the erase state E and memory cell voltage distributions of first to seventh fine-program states P1 to P7. Memory cells in the first to seventh fine-program states P1 to P7 may have fourth to tenth threshold voltages, respectively. The fourth threshold voltage has a greater voltage level than the threshold voltage of memory cells in the erase state E. The fourth to tenth threshold voltages may have progressively greater voltage levels. For example, during the fine-program operation, memory cells in the erase state E by the foggy-program operation may be programmed to form memory cell distributions of the erase state E and the first fine-program state P1. During the fine-program operation, memory cells in the first coarse-program state P01 by the coarse-program operation may be programmed to form memory cell distributions of the second and third fine-program states P2 and P3. During the fine-program operation, memory cells in the second coarse-program state P02 by the coarse-program operation may be programmed to form memory cell distributions of the fourth and fifth fine-program states P4 and P5. During the fine-program operation, memory cells in the third coarse-program state P03 by the coarse-program operation may be programmed to form memory cell distributions of the sixth and seventh fine-program states P6 and P7. The fine-program operation for memory cells in the erase state E and the first to third coarse-program states P01 to P03 may be repeated until the memory cell distributions of the erase state E and the first to seventh fine-program states P1 to P7 is formed. In an embodiment, after completion of the fine-program operation to form the memory cell distributions of the erase state E and the first fine-program state P1, the fine-program operation may be performed to form the memory cell distributions of the second and third fine-program states P2 and P3. After completion of the fine-program operation to form the memory cell distributions of the second and third fine-program states P2 and P3, the fine-program operation may be performed to form the memory cell distributions of the fourth and fifth fine-program states P4 and P5. After completion of the fine-program operation to form the memory cell distributions of the fourth and fifth fine-program states P4 and P5, the fine-program operation may be performed to form the memory cell distributions of the sixth and seventh fine-program states P6 and P7. After completion of the fine-program to form the memory cell distribution of the first fine-program state P1, the fine-verification may be performed using a verification voltage VF1 having a voltage level between the memory cell distributions of the erase state E and the first fine-program state P1. After completion of the fine-program operation to form the memory cell distribution of the second fine-program state P2, the fine-verification may be performed using a verification voltage VF2 having a voltage level between the memory cell voltage distributions of the first fine-program state P1 and the voltage of the second fine-program state P2. After completion of the fine-program to form the memory cell distribution of the third fine-program state P3, the fine-verification may be performed using a verification voltage VF3 having a voltage level between the memory cell voltage distributions of the second fine-program state P2 and the voltage of the third fine-program state P3. After completion of the fine-program to form the memory cell distribution of the fourth fine-program state P4 is performed, the fine-verification may be performed using a verification voltage VF4 having a voltage level between the memory cell voltage distributions of the third fine-program state P3 and the voltage of the fourth fine-program state P4. After completion of the fine-program to form the memory cell distribution of the fifth fine-program state P5, the fine-verification may be performed using a verification voltage VF5 having a voltage level between the memory cell voltage distributions of the fourth fine-program state P4 and the fifth fine-program state P5. After completion of the fine-program to form the memory cell distribution of the sixth fine-program state P6, the fine-verification may be performed using a verification voltage VF6 having a voltage level between the memory cell distributions of the fifth fine-program state P5 and the sixth fine-program state P6. After completion of the fine-program to form the memory cell distribution of the seventh fine-program state P7, the fine-verification may be performed using a verification voltage VF7 having a voltage level between the memory cell voltage distributions of the sixth fine-program state P6 and the seventh fine-program state P7.

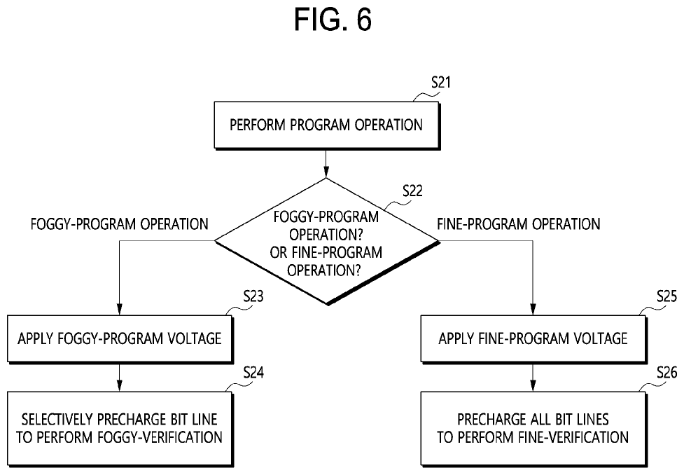

FIG. 6 is a flowchart illustrating a method of operating S21 a memory device 100 in accordance with an embodiment. When the coarse-program operation is performed at step S22, a coarse-program voltage is applied to a selected memory cell at step S23. At step S24, the coarse-program verification may be performed on the memory cell that underwent the coarse-program at step S23. During the coarse-program operation, most memory cells may be in the erase state E.

Referring now to FIGS. 1 and 4A, after having undergone the coarse-program operation, most memory cells may be in the erase state E. Therefore, when the plurality of page buffers PB1 to PBm precharge all bit lines BL1 to BLm during the coarse-verification, current may flow through most bit lines, which causes power consumption of the memory device 100 to increase. In accordance with an embodiment, power consumption of the memory device 100 may be reduced through a selective precharge of the bit lines to prior to, or as part of, the coarse-verification S24 during the coarse-program operation.

For example, at step S23 in FIG. 6, the memory device 100 may precharge only the bit line coupled to the selected memory cell to which the coarse-program voltage is applied at step S23 and might not precharge the bit line coupled to the memory cell, to which the coarse-program voltage is not applied. The coarse-verification may be performed for the precharged bit lines and might not be performed for the non-precharged bit line. By performing the coarse-verification only for the selected bit lines, the current consumption may be reduced during the coarse-verification. The control circuit 121 may disable the bit line precharge signal SAPRE during the coarse-verification.

If at step 522 the method steps on the right-hand side of the flow chart are executed, which are steps of the fine-program operation, the method/process depicted in FIG. 6 proceeds to step S25, whereat the fine-program voltage may be applied to the selected memory cell for the fine-programming. At step S26, the bit line is precharged for the fine-verification. The memory device 100 may precharge all the bit lines for the fine-verification. During the fine-verification, less than half of the memory cells may have threshold voltages lower than the verification voltage. Therefore, the power consumption of the memory device 100 might not be significant even if all the bit lines are precharged for the fine-verification. Additionally, the precharging of all the bit lines for the fine-verification may allow the memory device 100 to form more precise memory cell distributions.

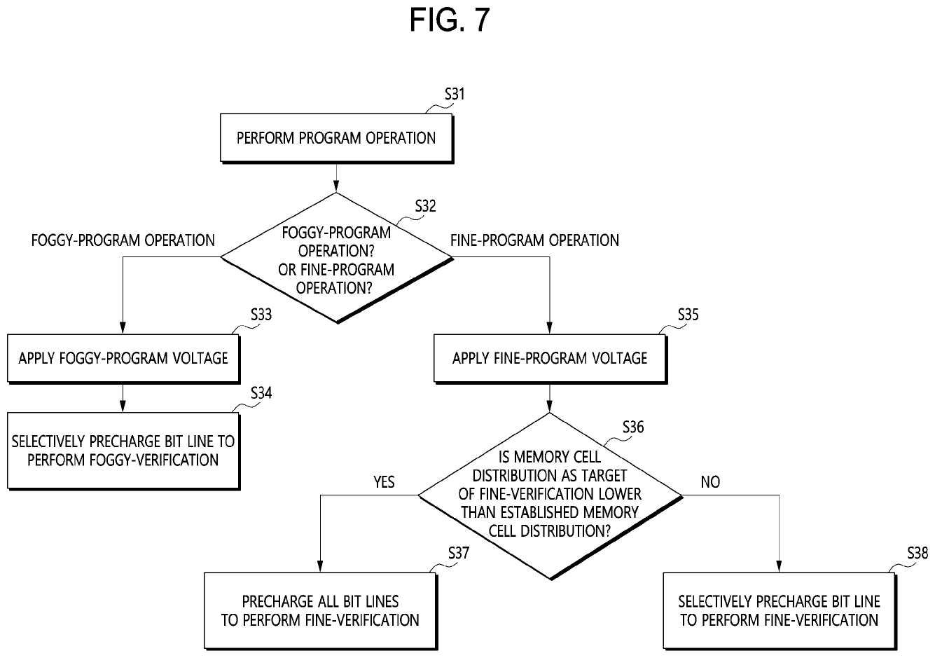

FIG. 7 is another flowchart illustrating an operation of the memory device 100 in accordance with an embodiment. Referring to FIG. 7, the memory device 100 may perform the program operation at step S31. At step S32, the memory device 100 may decide/determine whether the program operation is to be a coarse-program operation or a fine-program operation. If the program operation is determined as the coarse-program operation at step S32, the process may proceed to step S33. At step S33, the coarse-program voltage may be applied to the selected memory cell for the coarse-program. At step S34, the bit lines may be precharged for the coarse-verification. For performing the coarse-verification, the memory device 100 may selectively precharge the bit lines rather than precharging all of the bit lines. For example, at step S33, the memory device 100 may precharge the bit line coupled to the selected memory cell, to which the coarse-program voltage is applied, and might not precharge the bit line coupled to the memory cell, to which the coarse-program voltage is not applied. The coarse-verification may be performed for the precharged bit lines and might not be performed for the non-precharged bit lines. By performing the coarse-verification only for the selected bit lines, the current consumption may be reduced during the coarse-verification.

If the program operation is determined as the fine-program operation at step S32, the process may proceed to step S35. At step S35, the fine-program voltage may be applied to the selected memory cell for the fine-programming. At step S36, the memory cell distribution may be identified as the target of the fine-verification. At step S36, it may be determined whether the target memory cell distribution for the fine-verification is equal to or lower than an established memory cell distribution. The established memory cell distribution may be a middle one of memory cell distributions to be formed through the fine-program operation. For example, the established memory cell distribution may be the memory cell distribution of the third fine-program state P3, as illustrated in FIG. 4B. In an embodiment, the established memory cell distribution may vary depending on the characteristics of the memory device 100 or the needs of the user. For instance, the established memory cell distribution may vary to become a memory cell distribution of any of the first to seventh fine-program states P1 to P7. If the memory cell distribution as the target of fine-verification is determined as the same as or lower than the established memory cell distribution (“YES” at step S36), the process may proceed to step S37. At step S37, all bit lines may be precharged for the fine-verification. If the fine-verification is performed for the memory cell distribution that is lower than the established memory cell distribution, it may be determined that half or fewer of the memory cells are in the erase state E due to the fine-verification. Therefore, the memory device 100 may perform the fine-verification by precharging all bit lines. Despite the fine-verification through the precharging of all the bit lines, the power consumption of the memory device 100 might not be significant. In addition, if all bit lines are precharged for the fine-verification, the memory device 100 may form more sophisticated memory cell distributions.

If a target memory cell distribution of the fine-verification is determined as greater than the established memory cell distribution (“NO” at step S36), more than half of the memory cells may be determined as in the erase state E by the fine-verification operation. Therefore, for the fine-verification operation, the memory device 100 may selectively precharge the bit lines instead of precharging all the bit lines. For example, the memory device 100 may precharge the bit line coupled to the memory cell, to which the fine-program voltage is applied at step S35. The memory device 100 might not precharge the bit line coupled to the memory cell, to which the fine-program voltage is not applied at step S35. The fine-verification may be performed for the precharged bit line and might not be performed for the non-precharged bit line. By performing the fine-verification only for the selected bit lines, the current consumption may be reduced during the fine-verification.

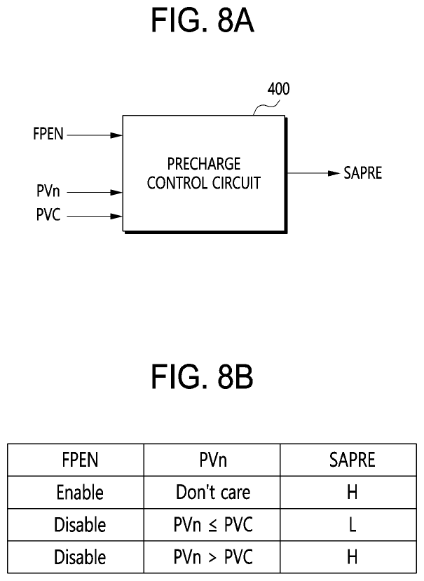

FIG. 8A is a diagram depicting precharge control “circuit” 400, which may be a component of the control circuit 121 illustrated in FIG. 1 which may be embodied as discrete electronic devices or program instructions executed by a processor, the functionality of the instructions implementing control circuit 121 operations.

FIG. 8B is a table illustrating operation states of the precharge control circuit 400. Referring now to FIG. 8A, the precharge control circuit 400 may receive a program operation information signal FPEN and a verification information signal PVn.

As shown in FIG. 8B, the precharge control circuit 400 may selectively generate different bit line precharge signals SAPRE, which may be one of the buffer control signals BCS in FIG. 1 and may be provided commonly to the plurality of page buffers PB1 to PBm of the buffer group 122, responsive to the program operation information signal FPEN and the verification information signal PVn.

The program operation information signal FPEN may indicate whether a program operation that is currently performed is a coarse-program operation or a fine-program operation. For example, the program operation information signal FPEN may be enabled when the current program operation is a coarse-program operation and may be disabled when the current program operation is a fine-program operation. The verification information signal PVn may include any information that can identify the distribution of target memory cells of the verification. For example, the verification information signal PVn may include the logic value of the memory cell distribution, the voltage level of the verification voltage, the number of times the program operation is performed, and so on.

When the program operation information signal FPEN is enabled, the precharge control circuit 400 may disable the bit line precharge signal SAPRE regardless of the verification information signal PVn. When the program operation information signal FPEN is disabled, the precharge control circuit 400 may selectively enable the bit line precharge signal SAPRE based on the verification information signal PVn. The precharge control circuit 400 may further receive a reference signal PVC. The reference signal PVC may be a reference value to be compared with the verification information signal PVn. The value of the reference signal PVC may be arbitrarily set.

When the program operation information signal FPEN is enabled, i.e., when the current program operation is the coarse-program operation, the precharge control circuit 400 may disable the bit line precharge signal SAPRE to a high logic level regardless of the verification information signal PVn (see “Don't care” in the table of FIG. 8). When the program operation information signal FPEN is disabled, i.e., when the current program operation is the fine-program operation, the precharge control circuit 400 may selectively enable the bit line precharge signal SAPRE according to the verification information signal PVn. The precharge control circuit 400 may enable the bit line precharge signal SAPRE to a low logic level when the value of the verification information signal PVn is equal to or less than the value of the reference signal PVC. The precharge control circuit 400 may disable the bit line precharge signal SAPRE to a high logic level when the value of the verification information signal PVn is greater than the value of the reference signal PVC. For example, referring to FIG. 4B, the verification information signal PVn may have values corresponding to the respective memory cell distributions of the erase state E and the first to seventh fine-program states P1 to P7. In this case, the reference signal PVC may have a value corresponding to the memory cell distribution of the third fine-program state P3. Therefore, when the verification information signal PVn has any of the values corresponding to the respective memory cell distributions of the erase state E and the first to third fine-program states P1 to P3, the precharge control circuit 400 may enable the bit line precharge signal SAPRE to a low logic level. When the verification information signal PVn has any of the values corresponding to the respective memory cell distributions of the fourth to seventh fine-program states P4 to P7, the precharge control circuit 400 may disable the bit line precharge signal SAPRE to a high logic level.

In an embodiment, the verification information signal PVn may be associated with the logic value of the memory cell distribution. For example, the memory cell distribution of the erase state E may correspond to a logic value of 1, 1, 1, the memory cell distribution of the first fine-program state P1 may correspond to a logic value of 1, 1, 0, the memory cell distribution of the second fine-program state P2 may correspond to a logic value of 1, 0, 1, and the memory cell distribution of the third fine-program state P3 may correspond to a logic value of 1, 0, 0. The memory cell distribution of the fourth fine-program state P4 may correspond to a logic value of 0, 1, 1, the memory cell distribution of the fifth fine-program state P5 may correspond to a logic value of 0, 1, 0, the memory cell distribution of the sixth fine-program state P6 may correspond to a logic value of 0, 0, 1, and the memory cell distribution of the seventh fine-program state P7 may correspond to a logic value of 0, 0, 0. In this case, the reference signal PVC may have a logic value of 1, 0, 0. The precharge control circuit 400 may selectively enable the bit line precharge signal SAPRE by comparing the logic value of the verification information signal PVn with the logic value of the reference signal PVC. The precharge control circuit 400 may enable the bit line precharge signal SAPRE to the low logic level when the logic value of the verification information signal PVn is equal to or less than the logic value of the reference signal PVC. The precharge control circuit 400 may disable the bit line precharge signal SAPRE to the high logic level when the logic value of the verification information signal PVn is greater than the logic value of the reference signal PVC. In an embodiment, depending on the characteristics of the memory device 100, the logic value of the reference signal PVC may vary in various ways. For example, the reference signal PVC may have a logic value of 1, 0, 1, or 0, 0, 1.

In an embodiment, the verification information signal PVn may be associated with the voltage level of the verification voltage used during the verification. For example, the reference signal PVC may have a voltage level between the memory cell distributions of the third fine-program state P3 and the fourth fine-program state P4. If provided as the verification information signal PVn is one of the verification voltage VF1 between the memory cell distributions of the erase state E and the first fine-program state P1, the verification voltage VF2 between the memory cell distributions of the first fine-program state P1 and the second fine-program state P2, the verification voltage VF3 between the memory cell distributions of the second fine-program state P2 and the third fine-program state P3, and the verification voltage VF4 between the memory cell distributions of the third fine-program state P3 and the fourth fine-program state P4, the precharge control circuit 400 may enable the bit line precharge signal SAPRE to the low logic level. If provided as the verification information signal PVn is one of the verification voltage VF5 between the memory cell distributions of the fourth fine-program state P4 and the fifth fine-program state P5, the verification voltage VF6 between the memory cell distributions of the fifth fine-program state P5 and the sixth fine-program state P6 and the verification voltage VF7 between the memory cell distributions of the sixth fine-program state P6 and the seventh fine-program state P7, the precharge control circuit 400 may disable the bit line precharge signal SAPRE to the high logic level. In an embodiment, the voltage level of the reference signal PVC may vary depending on the characteristics of the memory device 100. For example, the reference signal PVC may have a voltage level between the memory cell distributions of the second fine-program state P2 and the third fine-program state P3 or between the memory cell distributions of the fourth fine-program state P4 and the fifth fine-program state P5.

In an embodiment, the verification information signal PVn may be related to the number of times the program operation is performed. The fine program operation may be performed to sequentially form the memory cell distribution of the erase state E to the memory cell distribution of the seventh fine-program state P7. The number of times the program operation is required to be performed to form each of the erase state E and the first to seventh fine-program states P1 to P7 may be pre-set. In this case, the reference signal PVC may correspond to the number of times the fine program operation is required to be performed to form the memory cell distribution of the third fine-program state P3. The verification information signal PVn may be generated by counting the number of times the fine program operation is performed. The precharge control circuit 400 may enable the bit line precharge signal SAPRE to the low logic level when the counted number of times is equal to or less than the value of the reference signal PVC. The precharge control circuit 400 may disable the bit line precharge signal SAPRE to the high logic level when the counted number of times is greater than the value of the reference signal PVC. In an embodiment, the value of the reference signal PVC may vary according to the characteristics of the memory device 100. For example, the reference signal PVC may correspond to the number of times the fine program operation is required to be performed to form the memory cell distribution of the second fine-program state P2, or the fourth fine-program state P4.

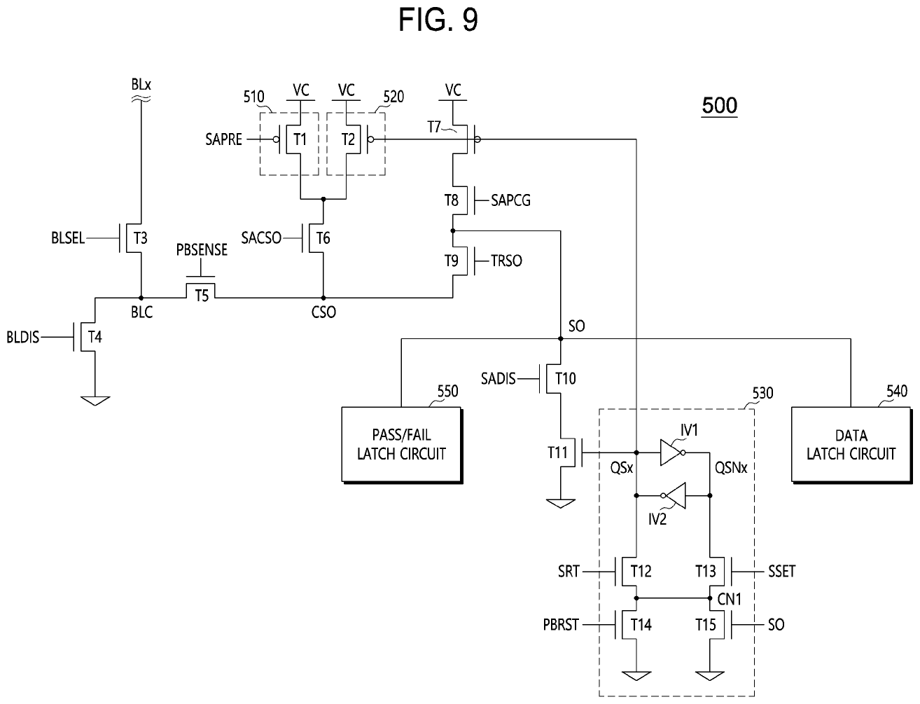

FIG. 9 is an illustration of a page buffer 500 in accordance with an embodiment. The page buffer 500 may be applied to each of the page buffers PB1 to PBm shown in FIG. 1.

The page buffer 500 may be coupled to the bit line BLx. During a program operation, the page buffer 500 may detect and verify the data stored in the memory cell coupled to the bit line BLx. In an embodiment, the page buffer 500 may read the data from the memory cell coupled to the bit line BLx during a read operation. The page buffer 500 may precharge the bit line BLx to perform the verification or the read operation. The page buffer 500 may precharge the bit line BLx based on at least one of the bit line precharge signal SAPRE and a latch signal QSx. The page buffer 500 may receive the bit line precharge signal SAPRE from the precharge control circuit 400 shown in FIG. 8. When the bit line precharge signal SAPRE is enabled, the page buffer 500 may precharge the bit line BLx regardless of the latch signal QSx. When the bit line precharge signal SAPRE is disabled, the page buffer 500 may precharge the bit line BLx based on the latch signal QSx. The page buffer 500 may selectively precharge the bit line BLx based on the logic level of the latch signal QSx. For example, the page buffer 500 may precharge the bit line BLx when the latch signal QSx has a low logic level and might not precharge the bit line BLx when the latch signal QSx has a high logic level.

The page buffer 500 may include a first precharge circuit 510, a second precharge circuit 520 and a sensing latch circuit 530. The first precharge circuit 510 may be coupled to the bit line BLx via a current sensing node CSO and may receive the bit line precharge signal SAPRE and a core voltage VC. The core voltage VC may be an internal voltage of the memory device 100 and may have an arbitrary voltage level. For example, the core voltage VC may be high enough to invert the latch value of the sensing latch circuit 530. The first precharge circuit 510 may precharge the bit line BLx to the core voltage VC based on the bit line precharge signal SAPRE. The first precharge circuit 510 may apply the core voltage VC to the bit line BLx to precharge the bit line BLx when the bit line precharge signal SAPRE is enabled. The first precharge circuit 510 might not apply the core voltage VC to the bit line BLx when the bit line precharge signal SAPRE is disabled. The second precharge circuit 520 is coupled to the bit line BLx via the current sensing node CSO and may receive the latch signal QSx and the core voltage VC. The second precharge circuit 520 may precharge the bit line BLx to the core voltage VC based on the latch signal QSx. The second precharge circuit 520 may apply the core voltage VC to the bit line BLx to precharge the bit line BLx when the latch signal QSx has a low logic level. The second precharge circuit 520 might not apply the core voltage VC to the bit line BLx when the latch signal QSx has a high logic level.

The sensing latch circuit 530 may detect the voltage level of a sensing node SO, which is coupled to the bit line BLx. The sensing node SO may be coupled to the bit line BLx via the current sensing node CSO. By detecting the voltage level of the sensing node SO, the sensing latch circuit 530 may generate the latch signal QSx. For example, when the voltage level of the sensing node SO become raised to a sufficient level, the sensing latch circuit 530 may generate and latch the latch signal QSx having a high logic level. When the voltage level of the sensing node SO does not become raised to a sufficient level, the sensing latch circuit 530 may generate and latch the latch signal QSx having a low logic level. When the voltage level of the sensing node SO becomes equal to or greater than the threshold of the sensing latch circuit 530, the sensing latch circuit 530 may invert the logic level of the latch signal QSx. During the verification, the sensing latch circuit 530 may set the logic value of the latch signal QSx based on the program data and the voltage level of the sensing node SO. If the same as each other are the logic value of the program data programmed in the memory cell coupled to the bit line BLx coupled to the page buffer 500 and the logic value of the memory cell distribution that is the target of the verification, the sensing latch circuit 530 may set the latch signal QSx to a low logic level. If different from each other are the logic value of the program data and the logic value of the target memory cell distribution of the verification, the sensing latch circuit 530 may set the latch signal QSx to a high logic level.

The page buffer 500 may further include a data latch circuit 540. The data latch circuit 540 may temporarily store the program data that has been programmed into the memory cell coupled to the bit line BLx. During the verification, the data latch circuit 540 may change the voltage level of the sensing node SO depending on the logic value of the program data temporarily stored therein and the logic value of the target memory cell distribution of the verification. For example, during the program operation on a triple level cell (TLC), the data latch circuit 540 may temporarily store therein the least significant bit (LSB), the central significant bit (CSB) and the most significant bit (MSB) of the program data. If the program data temporarily stored in the data latch circuit 540 matches the logic value of the target memory cell distribution of the verification, the data latch circuit 540 may maintain the voltage level of the sensing node SO to a high logic level. If the program data temporarily stored in the data latch circuit 540 does not match the logic value of the target memory cell distribution of the verification, the data latch circuit 540 may change the voltage level of the sensing node SO to a low logic level. For example, referring to FIG. 5A, if the program data has a logic value corresponding to the memory cell distribution of the first coarse-program state P01 and the coarse-verification is performed for the memory cell distribution of the first coarse-program state P01, the data latch circuit 540 may maintain the voltage level of the sensing node at a high logic level. If the program data has a logic value corresponding to the memory cell distribution of the first coarse-program state P01 and the coarse-verification is performed for the memory cell distribution of the second or third coarse-program state P02 or P03, the data latch circuit 540 may change the voltage level of the sensing node SO at a low logic level. Referring to FIG. 5B, if the program data has a logic value corresponding to the memory cell distribution of the fifth fine-program state P5 and the fine-verification is performed for the memory cell distribution of the fifth fine-program state P5, the data latch circuit 540 may maintain the voltage level of the sensing node SO at a high logic level. If the program data has a logic value corresponding to the memory cell distribution of the fifth fine-program state P5 and the fine-verification is performed for the memory cell distribution of the sixth or seventh fine-program state P6 or P7, the sensing node SO may change the voltage level to a low logic level. Therefore, based on the temporarily stored program data and the target memory cell distribution of the verification, the data latch circuit 540 may change the voltage level of the sensing node SO. The sensing latch circuit 530 may control the precharge operation to be selectively performed only for the bit line coupled to the memory cell corresponding to the target memory cell distribution of the verification by setting the logic level of the latch signal QSx based on the voltage level of the sensing node SO set by the data latch circuit 540.

The first precharge circuit 510 may include a first transistor T1 and the second precharge circuit 520 may include a second transistor T2. The first and second transistors T1 and T2 may be P-channel MOS transistors. The page buffer 500 may further include a third transistor T3, fourth transistor T4, fifth transistor T5, sixth transistor T6, seventh transistor T7, eighth transistor T8, ninth transistor T9, tenth transistor T10 and eleventh transistor T11. The third to sixth transistors T3 to T6 and the eighth to eleventh transistors T8 to T11 may be N-channel MOS transistors and the seventh transistor T7 may be a P-channel MOS transistor. The gate of the first transistor T1 may receive the bit line precharge signal SAPRE and the source of the first transistor T1 may receive the core voltage VC. The drain of the first transistor T1 may be coupled to the drain of the sixth transistor T6. When the bit line precharge signal SAPRE has a low logic level, the first transistor T1 may apply the core voltage VC to the drain of the sixth transistor T6. The gate of the second transistor T2 may receive the latch signal QSx and the source of the second transistor T2 may receive the core voltage VC. The drain of the second transistor T2 may be coupled to the drain of the sixth transistor T6. When the latch signal QSx has a low logic level, the second transistor T2 may apply the core voltage VC to the drain of the sixth transistor T6. The gate of the third transistor T3 may receive a bit line selection signal BLSEL. One of the drain and source of the third transistor T3 may be coupled to the bit line BLx and the other of the drain and source of the third transistor T3 may be coupled to a bit line connection node BLC. The bit line selection signal BLSEL may be one of the buffer control signals BCS provided from the control circuit 121 illustrated in FIG. 1 and may be for connecting the bit line BLx to the page buffer 500. The gate of the fourth transistor T4 may receive a bit line discharge signal BLDIS, the drain of the fourth transistor T4 may be coupled to the bit line connection node BLC and the source of the fourth transistor T4 may be coupled to the ground voltage. The fourth transistor T4 may discharge charge on the bit line BLx based on the bit line discharge signal BLDIS. The bit line discharge signal BLDIS may be one of the buffer control signals BCS provided from the control circuit 121 and may be for discharging the bit line BLx when the program operation is completed. The gate of the fifth transistor T5 may receive a page buffer sensing signal PBSENSE. One of the drain and source of the fifth transistor T5 may be coupled to the bit line connection node BLC and the other of the drain and source of the fifth transistor T5 may be coupled to the current sensing node CSO. When the page buffer sensing signal PBSENSE has a high logic level, the fifth transistor T5 may connect the bit line connection node BLC to the current sensing node CSO. The page buffer sensing signal PBSENSE may be one of the buffer control signals BCS.

The gate of the sixth transistor T6 may receive a current sensing signal SACSO and the drain of the sixth transistor T6 may be commonly coupled to the drains of the first and second transistors T1 and T2. The source of the sixth transistor T6 may be coupled to the current sensing node CSO. When the current sensing signal SACSO has a high logic level, the sixth transistor T6 may “turn on,” connecting the common-connected drains of the first and second transistors T1 and T2 to the current sensing node CSO. The current sensing signal SACSO may be one of the buffer control signals BCS. The gate of the seventh transistor T7 may receive the latch signal QSx and the source of the seventh transistor T7 may receive the core voltage VC. The gate of the eighth transistor T8 may receive a first sensing node precharge signal SAPCG and the drain of the eighth transistor T8 may be coupled to the drain of the seventh transistor T7. The first sensing node precharge signal SAPCG may be one of the buffer control signals BCS provided from the control circuit 121 and may be for precharging the sensing node SO to the core voltage VC. When the first sensing node precharge signal SAPCG has a high logic level, the eighth transistor T8 may connect the drain of the seventh transistor T7 to the sensing node SO. The gate of the ninth transistor T9 may receive a node connection signal TRSO. One of the drain and source of the ninth transistor T9 may be coupled to the sensing node SO and the other of the drain and source of the ninth transistor T9 may be coupled to the current sensing node CSO. When the node connection signal TRSO has a high logic level, the ninth transistor T9 may connect the sensing node SO and the current sensing node CSO to each other. The node connection signal TRSO may be one of the buffer control signals BCS provided from the control circuit 121 and may be for changing the voltage level of the sensing node SO depending on the voltage level of the bit line BLx. The gate of the tenth transistor T10 may receive a sensing node discharge signal SADIS and the drain of the tenth transistor T10 may be coupled to the sensing node SO. The sensing node discharge signal SADIS may be one of the buffer control signals BCS. The gate of the eleventh transistor T11 may receive the latch signal QSx and the drain of the eleventh transistor T11 may be coupled to the source of the tenth transistor T10. The source of the eleventh transistor T11 may be coupled to the ground voltage. When the sensing node discharge signal SADIS has a high logic level, the tenth transistor T10 may connect the sensing node SO to the drain of the eleventh transistor T11. When the latch signal QSx has a high logic level, the eleventh transistor T11 may discharge the sensing node SO by providing the ground voltage to the source of the tenth transistor T10.

The page buffer 500 may include a pass/fail latch circuit 550. The pass/fail latch circuit 550 may store a result of the verification. For example, the pass/fail latch circuit 550 may store a verification latch signal having a low logic level when the verification result is a pass during the program operation and may store the verification latch signal having a high logic level when the verification result is a fail during the program operation. In an alternate and equivalent embodiment and as design choice, the pass/fail latch circuit 550 may store a verification latch signal having a high logic level when the verification result is a pass during the program operation and may store the verification latch signal having a low logic level when the verification result is a fail during the program operation. When the verification is performed later, the pass/fail latch circuit 550 may change the voltage level of the sensing node SO based on the logic level of the verification latch signal. For example, when a previous verification result was a pass, the pass/fail latch circuit 550 may change, based on the verification latch signal, the voltage level of the sensing node SO to the low logic level during the current verification. When the previous verification result was a fail, the pass/fail latch circuit 550 might not change, based on the verification latch signal, the voltage level of the sensing node SO to the low logic level during the current verification. The pass/fail latch circuit 550 may prevent the reversal of the logic level of the latch signal of the sensing latch circuit 530 by changing the voltage level of the sensing node SO to the low logic level.

The sensing latch circuit 530 may include a first inverter IV1, a second inverter IV2, a twelfth transistor T12, a thirteenth transistor T13, a fourteenth transistor T14 and a fifteenth transistor T15. The input node of the first inverter IV1 may be coupled to the output node of the second inverter IV2. The output node of the first inverter IV1 may be coupled to the input node of the second inverter IV2. A complementary signal QSNx of the latch signal QSx may be output from the output node of the first inverter IV1 and the latch signal QSx may be output from the output node of the second inverter IV2. The twelfth to fifteenth transistors T12 to T15 may all be N-channel MOS transistors. The gate of the twelfth transistor T12 may receive a sensing reset signal SRST. The drain of the twelfth transistor T12 may be commonly coupled to the input node of the first inverter IV1 and the output node of the second inverter IV2. The source of the twelfth transistor T12 may be coupled to a first common node CN1. The gate of the thirteenth transistor T13 may receive a sensing set signal SSET. The drain of the thirteenth transistor T13 may be commonly coupled to the output node of the first inverter IV1 and the input node of the second inverter IV2. The source of the thirteenth transistor T13 may be coupled to the first common node CN1. The gate of the fourteenth transistor T14 may receive a page buffer reset signal PBRST. The drain of the fourteenth transistor T14 may be coupled to the first common node CN1 and the source of the fourteenth transistor T14 may be coupled to the ground voltage. The gate of the fifteenth transistor T15 may be coupled to the sensing node SO. The drain of the fifteenth transistor T15 may be coupled to the first common node CN1 and the source of the fifteenth transistor T15 may be coupled to the ground voltage. The sensing reset signal SRST, the sensing set signal SSET and the page buffer reset signal PBRST may be included in the buffer control signals BCS illustrated in FIG. 1. During the verification, the sensing node SO may be precharged to the core voltage VC and the sensing set signal SSET may be enabled to set the latch signal QSx to a high logic level. Subsequently, the sensing reset signal SRST may be enabled. If either the data latch circuit 540 or the pass/fail latch circuit 550 of the page buffer 500 keeps the voltage level of the sensing node SO to a high logic level, the latch signal QSx may be set to a low logic level. Conversely, if either the data latch circuit 540 or the pass/fail latch circuit 550 of the page buffer 500 changes the voltage level of the sensing node SO to a low logic level, the latch signal QSx may be maintained to a high logic level. Therefore, during the verification, if the program data programmed into the memory cell coupled to the bit line BLx coupled to the page buffer 500 is the same as the logic value of the target memory cell distribution of the verification or the result of a previous verification was a fail, the latch signal QSx may be set to a low logic level and the second precharge circuit 520 may precharge the bit line BLx based on the latch signal QSx.

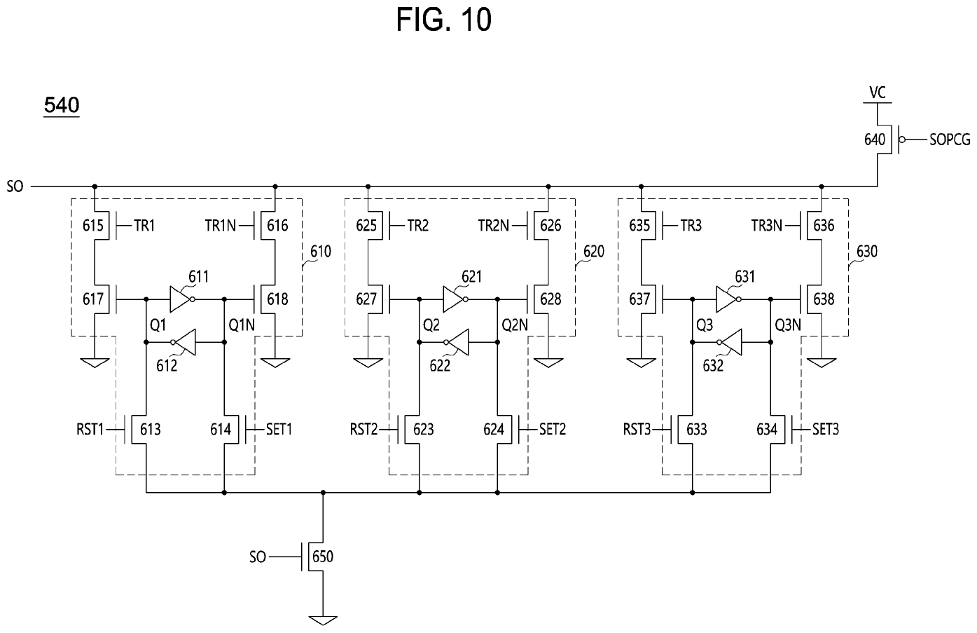

FIG. 10 is a diagram illustrating the configuration of the data latch circuit 540 illustrated in FIG. 9. Referring to FIG. 10, the data latch circuit 540 may include a first latch circuit 610, a second latch circuit 620, a third latch circuit 630, a precharge transistor 640 and a discharge transistor 650. When the program operation is performed on the TLC by the memory device 100, the data latch circuit 540 may include three (3) latch circuits. Depending on the type of program operation performed by the memory device 100, the number of latch circuits included in the data latch circuit 540 may vary. The first latch circuit 610 may be coupled to the sensing node SO and may store therein the logic value corresponding to the LSB of the program data. The second latch circuit 620 may be coupled to the sensing node SO and may store therein the logic value corresponding to the CSB of the program data. The third latch circuit 630 may be coupled to the sensing node SO and may store therein the logic value corresponding to the MSB of the program data. The first latch circuit 610 may include a first inverter 611, a second inverter 612, a first transistor 613, a second transistor 614, a third transistor 615, a fourth transistor 616, a fifth transistor 617 and a sixth transistor 618. The input node of the first inverter 611 may be coupled to the output node of the second inverter 612, and a first data latch signal Q1 may be stored at the output node of the second inverter 612. For example, the logic level of the first data latch signal Q1 may correspond to the logic level of the LSB of the program data. The output node of the first inverter 611 may be coupled to the input node of the second inverter 612, and a complementary signal Q1N of the first data latch signal Q1 may be stored at the output node of the first inverter 611. The first to sixth transistors 613 to 618 may be N-channel MOS transistors. The gate of the first transistor 613 may receive a first reset signal RST1, and the drain of the first transistor 613 may be commonly coupled to the input node of the first inverter 611 and the output node of the second inverter 612, and the source of the first transistor 613 may be coupled to a second common node CN2. The gate of the second transistor 614 may receive a first set signal SET1, and the drain of the second transistor 614 may be commonly coupled to the output node of the first inverter 611 and the input node of the second inverter 612, and the source of the second transistor 614 may be coupled to the second common node CN2. The gate of the third transistor 615 may receive a first transmission signal TR1, and the drain of the third transistor 615 may be coupled to the sensing node SO. The gate of the fourth transistor 616 may receive a complementary signal TR1N of the first transmission signal TR1, and the drain of the fourth transistor 616 may be coupled to the sensing node SO. The gate of the fifth transistor 617 may receive the first data latch signal Q1, and the drain of the fifth transistor 617 may be coupled to the source of the third transistor 615, and the source of the fifth transistor 617 may be coupled to the ground voltage. The gate of the sixth transistor 618 may receive the complementary signal Q1N of the first data latch signal Q1, and the drain of the sixth transistor 618 may be coupled to the source of the fourth transistor 616, and the source of the sixth transistor 618 may be coupled to the ground voltage. The first reset signal RST1, the first set signal SET1, the first transmission signal TR1 and the complementary signal TR1N of the first transmission signal TR1 can be included in the buffer control signals BCS of FIG. 1.

The second latch circuit 620 may include a first inverter 621, a second inverter 622, a first transistor 623, a second transistor 624, a third transistor 625, a fourth transistor 626, a fifth transistor 627 and a sixth transistor 628. The input node of the first inverter 621 may be coupled to the output node of the second inverter 622, and a second data latch signal Q2 may be stored at the output node of the second inverter 622. For example, the logic level of the second data latch signal Q2 may correspond to the logic level of the CSB of the program data. The output node of the first inverter 621 may be coupled to the input node of the second inverter 622, and a complementary signal Q2N of the second data latch signal Q2 may be stored at the output node of the first inverter 621. The first to sixth transistors 623 to 628 may be N-channel MOS transistors. The gate of the first transistor 623 may receive a second reset signal RST2, and the drain of the first transistor 623 may be commonly coupled to the input node of the first inverter 621 and the output node of the second inverter 622. The source of the first transistor 623 may be coupled to the second common node CN2. The gate of the second transistor 624 may receive a second set signal SET2, and the drain of the second transistor 624 may be commonly coupled to the output node of the first inverter 621 and the input node of the second inverter 622. The source of the second transistor 624 may be coupled to the second common node CN2. The gate of the third transistor 625 may receive a second transmission signal TR2, and the drain of the third transistor 625 may be coupled to the sensing node SO. The gate of the fourth transistor 626 may receive a complementary signal TR2N of the second transmission signal TR2, and the drain of the fourth transistor 626 may be coupled to the sensing node SO. The gate of the fifth transistor 627 may receive the second data latch signal Q2, and the drain of the fifth transistor 627 may be coupled to the source of the third transistor 625. The source of the fifth transistor 627 may be coupled to the ground voltage. The gate of the sixth transistor 628 may receive the complementary signal Q2N of the second data latch signal Q2, and the drain of the sixth transistor 628 may be coupled to the source of the fourth transistor 626. The source of the sixth transistor 628 may be coupled to the ground voltage. The second reset signal RST2, the second set signal SET2, the second transmission signal TR2 and the complementary signal TR2N of the second transmission signal TR2 may be included in the buffer control signals BCS of FIG. 1.

The third latch circuit 630 may include a first inverter 631, a second inverter 632, a first transistor 633, a second transistor 634, a third transistor 635, a fourth transistor 636, a fifth transistor 637 and a sixth transistor 638. The input node of the first inverter 631 may be coupled to the output node of the second inverter 632, and a third data latch signal Q3 may be stored at the output node of the second inverter 632. For example, the logic level of the third data latch signal Q3 may correspond to the logic level of the MSB of the program data. The output node of the first inverter 631 may be coupled to the input node of the second inverter 632, and a complementary signal Q3N of the third data latch signal Q3 may be stored at the output node of the first inverter 631. The first through sixth transistors 633 to 638 may be N-channel MOS transistors. The gate of the first transistor 633 may receive a third reset signal RST3, the drain of the first transistor 633 may be commonly coupled to the input node of the first inverter 631 and the output node of the second inverter 632, and the source of the first transistor 633 may be coupled to the second common node CN2. The gate of the second transistor 634 may receive a third set signal SET3, the drain of the second transistor 634 may be commonly coupled to the output node of the first inverter 631 and the input node of the second inverter 632, and the source of the second transistor 634 may be coupled to the second common node CN2. The gate of the third transistor 635 may receive a third transmission signal TR3, and the drain of the third transistor 635 may be coupled to the sensing node SO. The gate of the fourth transistor 636 may receive a complementary signal TR3N of the third transmission signal TR3, and the drain of the fourth transistor 636 may be coupled to the sensing node SO. The gate of the fifth transistor 637 may receive the third data latch signal Q3, the drain of the fifth transistor 637 may be coupled to the source of the third transistor 635, and the source of the fifth transistor 637 may be coupled to the ground voltage. The gate of the sixth transistor 638 may receive a complementary signal Q3N of the third data latch signal Q3, the drain of the sixth transistor 638 may be coupled to the source of the fourth transistor 636, and the source of the sixth transistor 638 may be coupled to the ground voltage. The third reset signal RST3, the third set signal SET3, the third transmission signal TR3, and the complementary signal TR3N of the third transmission signal TR3 may be included in the buffer control signals BCS of FIG. 1.

The precharge transistor 640 may be a P-channel MOS transistor. The gate of the precharge transistor 640 may receive a second sensing node precharge signal SOPCG, the source of the precharge transistor 640 may receive the core voltage VC, and the drain of the precharge transistor 640 may be coupled to the sensing node SO. The second sensing node precharge signal SOPCG may be one of the buffer control signals BCS of FIG. 1. When the second sensing node precharge signal SOPCG is enabled at a low logic level, the precharge transistor 640 may precharge the sensing node SO to the voltage level of the core voltage VC. The discharge transistor 650 may be an N-channel MOS transistor. The gate of the discharge transistor 650 may be coupled to the sensing node SO. The drain of the discharge transistor 650 may be coupled to the second common node CN2. The source of the discharge transistor 650 may be coupled to the ground voltage.

During the program of the program operation, the first to third latch circuits 610, 620 and 630 may set the logic level of the first to third data latch signals Q1, Q2 and Q3 based on the first to third reset signals RST1, RST2 and RST3 and the first to third set signals SET1, SET2 and SET3. For example, during the program operation of programming the program data of 1, 1, 0, the second sensing node precharge signal SOPCG may be enabled to precharge the sensing node SO to the core voltage VC, and then the first set signal SET1, the second set signal SET2, and the third reset signal RST3, which have a high logic level, may be applied and the first reset signal RST1, the second reset signal RST2 and the third set signal SET3, which have a low logic level, may be applied. Through the second transistor 614 of the first latch circuit 610 and the discharge transistor 650, the complementary signal Q1N of the first data latch signal Q1 may be set to a low logic level and the first data latch signal Q1 may be set to a high logic level. Through the second transistor 624 of the second latch circuit 620 and the discharge transistor 650, the complementary signal Q2N of the second data latch signal Q2 may be set to a low logic level and the second data latch signal Q2 may be set to a high logic level. Through the first transistor 633 of the third latch circuit 630 and the discharge transistor 650, the third data latch signal Q3 may be set to a low logic level and the complementary signal Q3N of the third data latch signal Q3 may be set to a high logic level.

During the verification of the program operation, the first to third latch circuits 610, 620 and 630 may change the voltage level of the sensing node SO based on the first to third transmission signals TR1, TR2 and TR3 and the complementary signals TR1N, TR2N and TR3N of the first to third transmission signals TR1, TR2 and TR3. For example, the voltage level of the sensing node SO may be maintained at a high logic level when the complementary signal TR1N of the first transmission signal TR1, the complementary signal TR2N of the second transmission signal TR2, and the third transmission signal TR3 are applied and the first transmission signal TR1, the second transmission signal TR2, and the complementary signal TR3N of the third transmission signal TR3 are applied after the second sensing node precharge signal SOPCG is enabled and the sensing node SO is precharged to the core voltage VC. At this time, the complementary signal TR1N of the first transmission signal TR1, the complementary signal TR2N of the second transmission signal TR2, and the third transmission signal TR3 may have a high logic level and the first transmission signal TR1, the second transmission signal TR2, and the complementary signal TR3N of the third transmission signal TR3 may have a low logic level. On the contrary, when any of the first transmission signal TR1, the second transmission signal TR2, and the complementary signal TR3N of the third transmission signal TR3 becomes to have a high logic level, the data latch circuit 540 may change the voltage level of the sensing node SO to a low logic level. For example, when the first transmission signal TR1 of a high logic level is applied, the sensing node SO may be coupled to the ground voltage through the third transistor 615 and the fifth transistor 617, which may cause the voltage level of the sensing node SO to change to a low logic level.

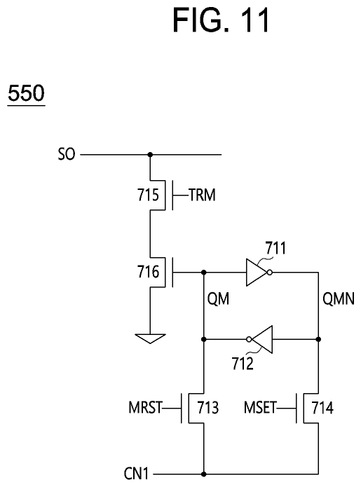

FIG. 11 is a diagram illustrating the configuration of the pass/fail latch circuit 550 illustrated in FIG. 9. Referring to FIG. 11, the pass/fail latch circuit 550 may include a first inverter 711, a second inverter 712, a first transistor 713, a second transistor 714, a third transistor 715 and a fourth transistor 716. The input node of the first inverter 711 may be coupled to the output node of the second inverter 712, and a verification latch signal QM may be stored at the output node of the second inverter 712. The output node of the first inverter 711 may be coupled to the input node of the second inverter 712, and a complementary signal QMN of the verification latch signal QM may be stored at the output node of the first inverter 711. The first to fourth transistors 713 to 716 may be N-channel MOS transistors. The gate of the first transistor 713 may receive a verification reset signal MRST, and the drain of the first transistor 713 may be commonly coupled to the input node of the first inverter 711 and the output node of the second inverter 712, and the source of the first transistor 713 may be coupled to the first common node CN1 of FIG. 9. The gate of the second transistor 714 may receive a verification set signal MSET, and the drain of the second transistor 714 may be commonly coupled to the output node of the first inverter 711 and the input node of the second inverter 712, and the source of the second transistor 714 may be coupled to the first common node CN1. The gate of the third transistor 715 may receive a verification transmission signal TRM, and the drain of the third transistor 715 may be coupled to the sensing node SO. The gate of the fourth transistor 716 may receive a verification latch signal QM, and the drain of the fourth transistor 716 may be coupled to the source of the third transistor 715, and the source of the fourth transistor 716 may be coupled to the ground voltage. The verification reset signal MRST, the verification set signal MSET and the verification transmission signal TRM may be included in the buffer control signals BCS of FIG. 1.

When the result of the verification is a pass during the program operation, the verification set signal MSET of a high logic level and the verification reset signal MRST of a low logic level may be applied and the verification latch signal QM may be set to a high logic level. When the result of the verification is a fail, the verification set signal MSET of a low logic level and the verification reset signal MRST of a high logic level may be applied and the verification latch signal QM may be set to a low logic level. Subsequently, when the verification is performed during the program operation, the verification transmission signal TRM of a high logic level may be applied. When the verification latch signal QM is set to a low logic level, the voltage level of the sensing node SO might not change. When the verification latch signal QM is set to a high logic level, the sensing node SO may be coupled to the ground voltage through the third transistor 715 and the fourth transistor 716 and the voltage level of the sensing node SO may change to low logic level.

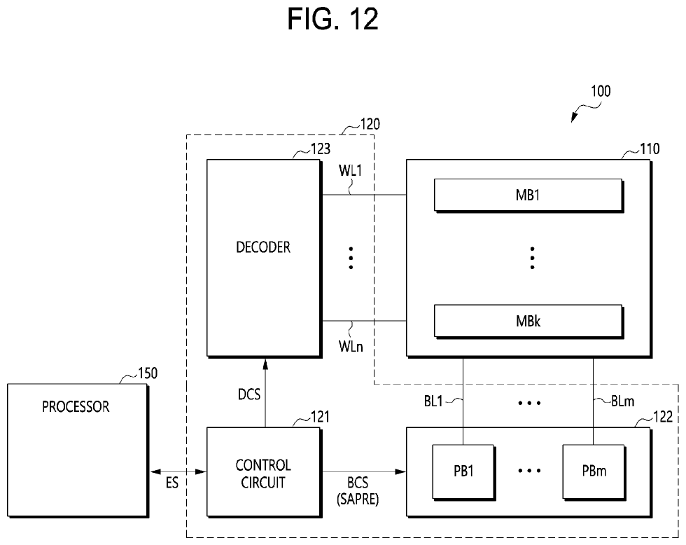

FIG. 12 illustrates a processor 150 coupled to a memory device 100 as shown in FIG. 1. The processor 150 is thus the “external device,” executing program instructions stored in the memory device 100. The processor 150, which can be part of a cellular telephone, a GPS navigation system, an automotive control system, reads data from and stores data in the memory device 100.

While certain embodiments have been described above, it will be understood to those skilled in the art that the embodiments described are by way of example only. Accordingly, the memory apparatus performing program operation and an operating method thereof should not be limited based on the described embodiments. Rather, the memory apparatus performing program operation and an operating method thereof described herein should only be limited in light of the claims that follow when taken in conjunction with the above description and accompanying drawings.

What is claimed is:

1. A memory device comprising:
a bit line coupled to a memory cell;
a precharge control circuit configured to generate a bit line precharge signal based on a program operation information signal; and
a page buffer configured to generate a latch signal based on program data and a voltage level of a sensing node, which is coupled to the bit line, and configured to precharge the bit line responsive to at least one of the bit line precharge signal and the latch signal.

2. The memory device of claim 1,
wherein the precharge control circuit is configured to disable the bit line precharge signal during a coarse-program operation, and
wherein the precharge control circuit is configured to enable the bit line precharge signal during a fine-program operation.

3. The memory device of claim 1,
wherein the page buffer is configured to precharge the bit line when the bit line precharge signal is enabled, and
wherein the page buffer is configured to precharge the bit line responsive to the latch signal, when the bit line precharge signal is disabled.

4. The memory device of claim 1, wherein the page buffer comprises:
a first precharge circuit configured to apply a core voltage to the bit line responsive to the bit line precharge signal;
a second precharge circuit configured to apply the core voltage to the bit line responsive to the latch signal; and
a sensing latch circuit configured to generate the latch signal responsive to the voltage level of the sensing node.

5. The memory device of claim 3, wherein the page buffer further comprises a data latch circuit configured to change the voltage level of the sensing node responsive to the program data.

6. The memory device of claim 3, wherein the page buffer further comprises a verification latch circuit configured to change the voltage level of the sensing node responsive to the verification latch signal.

7. A memory device comprising:
a bit line coupled to a memory cell;
a precharge control circuit configured to generate a bit line precharge signal responsive to at least one of: a program operation information signal and a verification information signal; and
a page buffer configured to generate a latch signal by sensing program data and a voltage level of a sensing node, which is coupled to the bit line, and configured to precharge the bit line responsive to at least one of: the bit line precharge signal and the latch signal.

8. The memory device of claim 7,
wherein the precharge control circuit is configured to disable the bit line precharge signal when the program operation information signal is a coarse-program operation.

9. The memory device of claim 7, wherein the precharge control circuit is configured to enable the bit line precharge signal when the program operation information signal is a fine-program operation and a value of the verification information signal is lower than a value of a reference signal.

10. The memory device of claim 7, wherein the precharge control circuit is configured to disable the bit line precharge signal when the program operation information signal is a fine-program operation and a value of the verification information signal is higher than a value of a reference signal.

11. The memory device of claim 7, wherein the verification information signal is at least one of: a logic value of a memory cell distribution;
a verification voltage; and a number of times that a program operation is performed.

12. The memory device of claim 7,
wherein the page buffer is configured to precharge the bit line regardless of the latch signal when the bit line precharge signal is enabled, and
wherein the page buffer is configured to precharge the bit line responsive to the latch signal when the bit line precharge signal is disabled.

13. The memory device of claim 7, wherein the page buffer includes:
a first precharge circuit configured to apply a core voltage to the bit line responsive to the bit line precharge signal;
a second precharge circuit configured to apply the core voltage to the bit line responsive to the latch signal; and
a sensing latch circuit configured to generate the latch signal responsive to the voltage level of the sensing node.

14. The memory device of claim 13, wherein the page buffer further comprises a data latch circuit configured to change the voltage level of the sensing node responsive to the program data.

15. The memory device of claim 13, wherein the page buffer further comprises a verification latch circuit configured to change the voltage level of the sensing node responsive to the verification latch signal.

16. A method of operating a memory device comprising a plurality of bit lines, the operating method comprising:
applying a program voltage to a plurality of memory cells; and
selectively precharging a plurality of bit lines to perform a verification when the program operation is a coarse-program operation, and precharging all the plurality of bit lines to perform the verification when the program operation is a fine-program operation.

17. The method of claim 16, wherein the selectively precharging a plurality of bit lines is performed responsive to a latch signal stored in a plurality of page buffers, which are respectively coupled to the plurality of bit lines.

18. The method of claim 17, wherein a logic level of the latch signal is set responsive to program data corresponding to the program voltage and a logic value of a memory cell distribution that is a target of the verification.

19. The method of claim 16, wherein performing the verification when the program operation is the fine-program operation comprises precharging all the plurality of bit lines to perform the verification when a memory cell distribution, which is a target of the verification, is the same as an established memory cell distribution or a lower memory cell distribution than the established memory cell distribution.

20. The method of claim 16, wherein performing the verification when the program operation is the fine-program operation comprises selectively precharging the plurality of bit lines to perform the verification when a memory cell distribution, which is a target of the verification, is a higher memory cell distribution than an established memory cell distribution.
